(19) United States
(12) Patent Application Publication
(10) Pub. No.: US 2008/0246491 A1
(43) Pub. Date: Oct. 9, 2008

(54) Scalable method for identifying cracks and fractures under wired or ball bonded bond pads

(75) Inventors: Ennis T. Ogawa, Austin, TX (US); Daryl R. Heussner, Allen, TX (US); Charles A. Odegard, McKinney, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/784,220

(22) Filed: Apr. 6, 2007

(51) Int. Cl. G01R 31/28

(52) U.S. Cl. 324/519; 324/526

(57) ABSTRACT

In a method and system for testing a presence of a crack (240) in a device under test (DUT) (190), a test system includes a bridge circuit (BC) (120) coupled to an electrical signal source (ESS) (110) capable of generating an electrical signal (102). The BC (120) includes four impedances that are coupled in a bridge structure having two floating nodes (132, 134). The DUT (190) includes a test bond pad (TBP) (192) and an access bond pad (ABP) (194). An impedance measurable across the TBP (192) and the ABP (194) is selectable as one of the four impedances. A stimulus (140) is provided to the DUT (190) to induce stress. A sensor (130) coupled across the two floating nodes (132, 134) detects a change in a value of the electrical signal measured across the two floating nodes (132, 134) in response to the stimulus (140). The change is triggered by the presence of the crack (240) under the TBP (192) caused by the stress, the crack (240) changing the impedance.

### BACKGROUND

The present disclosure relates generally to testing for defects in a semiconductor device, and more particularly to a system and method for testing presence of cracks and fractures within a device under test (DUT).

Manufacturers of electrical/electronic devices such as integrated circuits (ICs), including system-on-a-chip (SoC), radio frequency (RF) circuit devices, printed circuit boards, and other electronic circuits, typically use automatic test equipment (ATE), testers or similar other test systems to test the devices during the production process. The test systems are generally configured to apply a test signal to the DUT and measure its response to determine a pass or fail status.

Formation of a crack, fracture or similar other defect during the IC fabrication process is a growing concern that impacts the reliability of semiconductor devices. The crack may be formed due to presence of high stresses that may be induced during the fabrication process or during use. For example, some interconnection processes such as wirebonding or ball bonding may cause a crack in semiconductor materials due to high temperature induced stresses on a bond pad, thereby potentially affecting the integrity of structures disposed under the bond pad.

Present techniques for testing the electrical integrity of a bond pad are generally based on testing the electrical continuity between two points. Presence of a crack may or may not affect the electrical continuity. Therefore, a need exists to provide a method and system for checking a presence of a crack that may affect the reliability and performance of an interconnection such as a bond pad of a DUT.

### SUMMARY

Applicants recognize that stress induced cracking or fracture of semiconductor materials used in a back-end-of-line (BEOL) structure is a frequently observed phenomenon in the fabrication of semiconductor devices. Abnormalities in the process or defective semiconductor materials or both may also cause crack formation. Formation of cracks may be further complicated if the external environment including ambient gases are allowed to penetrate into the BEOL stack of the semiconductor device. The use of porous, low-k materials that are mechanically weaker than previously used silicon dioxide dielectrics may further increase the risk of crack formation. Additionally, crack dimensions may increase with time.

Applicants recognize the need for a non-destructive, repeatable, accurate, electrical measurement based method and system to test the electrical integrity of interconnection components such as a bond pad that may be subjected to induced stresses. The electrical properties of the bond pad are affected by a presence of a crack disposed below or under the bond pad. It would be desirable to detect a presence of a crack under a bond pad of the DUT, and determine whether the crack is hermetic (e.g., crack is not exposed to ambient gases) or non-hermetic (e.g., crack is exposed to ambient gases). Furthermore, it would be desirable to track changes in the crack dimensions that may evolve with time. Accordingly, it would be desirable to provide an improved method and system for testing a DUT, absent the disadvantages found in the prior methods discussed above.

The foregoing needs are addressed by the teachings of the present disclosure, which relates to a system and method for electrically testing a presence of a crack in a DUT. According to one embodiment, in a method and system for testing a presence of a crack in a device under test (DUT), a test system includes a bridge circuit (BC) coupled to an electrical signal source (ESS) capable of generating an electrical signal. The BC includes four impedances that are coupled in a bridge structure having two floating nodes. The DUT includes a test bond pad (TBP) and an access bond pad (ABP). An impedance measurable across the TBP and the ABP is selectable as one of the four impedances. A stimulus is provided to the DUT to induce stress. A sensor coupled across the two floating nodes detects a change in a value of the electrical signal measured across the two floating nodes in response to the stimulus. The change is triggered by the presence of the crack under the TBP caused by the stress, the crack changing the impedance.

In one aspect of the disclosure, a method for testing a device under test (DUT) includes providing an electrical signal to a bridge circuit. The bridge circuit includes four impedances coupled in a bridge structure having two floating nodes. One of the four impedances is an impedance measurable across a test bond pad and an access bond pad of the DUT. An initial value of the electrical signal is measured between the two floating nodes. Stress is induced in the DUT, e.g., by temperature cycling. A change in the electrical signal is detected in response to the stress. The change is indicative of a presence of a crack formed under a test bond pad in response to the induced stress. The impedance across the bond pads changes as a response to changes in the crack.

Several advantages are achieved by the method and system according to the illustrative embodiments presented herein. The embodiments advantageously provide for non-destructive repeatable, accurate, electrical measurement techniques to verify that the DUT is substantially free from a presence of a crack, fracture or similar defect disposed below interconnections such as bond pads. The embodiments advantageously provide an electrically sensitive bridge circuit to detect cracks by detecting a change in impedance (such as a capacitance) measurable between a test bond pad and an access bond pad. A dummy finger element structure is advantageously disposed under the test bond pad to form a capacitance. A formation of a crack causes a change in a dielectric property of the capacitance, and hence in a value of the capacitance. The dummy finger element does not substantially alter the interconnect footprint around bond pads and does not utilize excessive amounts of valuable real estate of an IC chip. Changes to the capacitance may be monitored over time, e.g., after burn-in, or after inducing environmental stress on the DUT. The embodiments advantageously provide information about a crack, e.g., whether a crack is hermetic or non-hermetic by measuring differences in the sign and magnitude of the change in the bridge circuit. The embodiments advantageously enable semiconductor device manufacturers to improve product quality and reliability, reduce the overall testing costs, and enable increased production.

### BRIEF DESCRIPTION OF THE DRAWINGS

FIG. 1 illustrates a block diagram of a test system for testing a device under test (DUT), according to an embodiment;

FIG. 2A illustrates a view in perspective of an internal structure of a portion of a DUT described with reference to FIG. 1, according to an embodiment;

FIG. 2B illustrates a view in perspective of a presence of a crack in an internal structure of a portion of a DUT described with reference to FIG. 2A, according to an embodiment;

FIG. 3 illustrates a layout of a plurality of bond pads of a DUT described with reference to FIGS. 1, 2A, and 2B, according to an embodiment;

FIG. 4 illustrates a schematic layout of a test reticle for parallel testing two DUT's, according to an embodiment; and

FIG. 5 is a flow chart illustrating a method for testing a device under test (DUT), according to an embodiment.

### DETAILED DESCRIPTION

Novel features believed characteristic of the present disclosure are set forth in the appended claims. The disclosure itself, however, as well as a preferred mode of use, various objectives and advantages thereof, will best be understood by reference to the following detailed description of an illustrative embodiment when read in conjunction with the accompanying drawings. The functionality of various circuits, devices or components described herein may be implemented as hardware (including discrete components, integrated circuits and systems-on-a-chip ‘SoC’), firmware (including application specific integrated circuits and programmable chips) and/or software or a combination thereof, depending on the application requirements.

Similarly, the functionality of various mechanical elements, members, or components for forming modules, sub-assemblies and assemblies assembled in accordance with a structure for an apparatus may be implemented using various materials and coupling techniques, depending on the application requirements. Descriptive and directional terms used in the written description such as top, bottom, left, right, and similar others, refer to the drawings themselves as laid out on the paper and not to physical limitations of the disclosure unless specifically noted. The accompanying drawings may not to be drawn to scale and some features of embodiments shown and described herein may be simplified or exaggerated for illustrating the principles, features, and advantages of the disclosure.

Many test systems use electrical connectivity tests to determine integrity of interconnections such as bond pads of a device under test (DUT). Presence of a crack may or may not affect the electrical continuity and hence may remain undetected. In addition, cracks may grow over time and degrade DUT performance. This problem may be addressed by a non-destructive, repeatable, accurate, electrical measurement based method and system to test the electrical integrity of interconnection components such as a bond pad that may be subjected to induced stresses. In the improved system and method, a formation of a crack below a bond pad is detectable by detecting a change in a capacitance formed between the bond pad under test and a dummy finger element formed under the bond pad of the DUT.

According to one embodiment, in a method and system testing a presence of a crack in a device under test (DUT), a test system includes a bridge circuit (BC) coupled to an electrical signal source (ESS) capable of generating an electrical signal. The BC includes four impedances that are coupled in a bridge structure having two floating nodes. The DUT includes a test bond pad (TBP) and an access bond pad (ABP). An impedance measurable across the TBP and the ABP is selectable as one of the four impedances. A stimulus is provided to the DUT to induce stress. A sensor coupled across the two floating nodes detects a change in a value of the electrical signal measured across the two floating nodes in response to the stimulus. The change is triggered by the presence of the crack under the TBP caused by the stress, the crack changing the impedance.

The following terminology may be useful in understanding the present disclosure. It is to be understood that the terminology described herein is for the purpose of description and should not be regarded as limiting.

Electrical Interconnect—A technique to provide electrical coupling between two electrical elements. The electrical interconnect uses conductive material such as metal (e.g., aluminum, copper, silver, gold, and similar others including alloys) to achieve the electrical interconnection. The interconnect, which is an essential part of any semiconductor device, may include conductive traces, conductive bumps, solder bumps, vias, metal planes, bond wires, metal lands, metal planes, bond wire areas, bond pads, conductive pads, metal studs, and similar others.

Semiconductor Package (or Package)—A semiconductor package provides the physical and electrical interface to at least one integrated circuit (IC) or die included in a semiconductor device for connecting the IC to external circuits. The package protects the IC from damage, contamination, and stress that result from factors such as handling, heating, and cooling.

Semiconductor Device—A semiconductor device is an electronic component that utilizes electronic properties of semiconductor materials to perform a desired function. A semiconductor device may be manufactured as a single discrete device or as one or more ICs packaged into a module.

Configuration—Describes a set up of an element, a circuit, a package, an electronic device, and similar other, and refers to a process for setting, defining, or selecting particular properties, parameters, or attributes of the device prior to its use or operation. Some configuration attributes may be selected to have a default value. For example, a particular value of an impedance may be configured for each one of the four arms of a bridge circuit to balance the bridge.

Ball grid array (BGA)—A type of chip package type that enables direct mounting of the chip to a substrate or printed circuit board via solder balls or bumps. The solder balls or bumps are arranged in a grid-style array and found on the underside of the chip to make the electrical connection to the outside.

Low k dielectric—A dielectric material having a constant k value of less than 4.5, preferably below 2.5. Low k dielectric materials may be formed from hybrids of organic and silicate materials, such as organosilicate glass (OSG).

Wirebond package—Wirebonding is an electrical interconnection technique that uses thin wires and a bonding agent such as a heat, pressure and ultrasound energy or a combination thereof. Semiconductor device packages that use wirebonding (referred to as a ‘wirebond package’) include ball grid array (single chip and multi-chip), ceramic and plastic quad flat packages, chip scale packages, and a chip on board (COB) package.

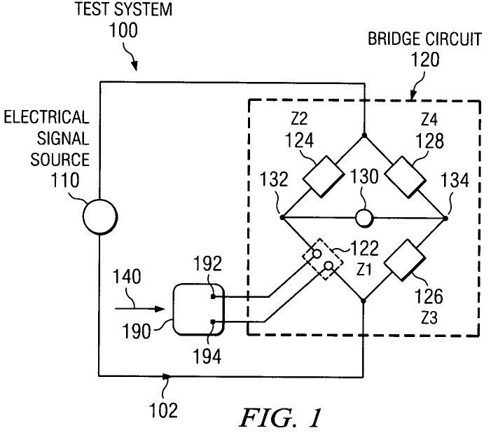

The type of stresses induced in a semiconductor device that cause formation of a crack, fracture, or similar other defect may include tension, compression, shear or a combination thereof. In actual use or during the testing, the semiconductor device and its packaging materials are subjected to repeated load/stress cycles caused by stimulus such as vibration, oscillation, temperature cycling, and similar others. Typical examples of stress tests which may be performed include high temperature storage test (e.g., 100 to 150 degrees Centigrade) for creep or void testing, temperature cycling test (0 to 125 degrees Centigrade or 65 to 150 degrees Centigrade) for fatigue testing, and autoclave or pressure cooker test (at 121 degrees Centigrade and 100 relative humidity) for corrosion and mechanical testing. Semiconductor device manufacturers are often challenged with detecting presence of a crack before and after stress inducing processes such as wire bonding or ball bonding for BGA connections. Test systems providing non-destructive repeatable, accurate, electrical measurement of defects such as a crack below a bond pad of a DUT are described with reference to FIGS. 1, 2A, 2B, 3, 4, and 5.

FIG. 1 illustrates a block diagram of a test system 100 for testing a device under test (DUT) 190, according to an embodiment. The test system 100 includes an electrical signal source 110 operable to provide an electrical signal 102 to a bridge circuit 120. In an embodiment, the electrical signal source 110 provides one of a direct current (DC) signal and an alternating current (AC) signal. The bridge circuit 120 includes four impedances forming a bridge structure. The bridge structure includes a first impedance Z1 122 coupled in series with a second impedance Z2 124 to form a first node 132, and a third impedance Z3 126 is coupled in series with a fourth impedance Z4 128 to form a second node 134. Each one of the four impedances forms a corresponding arm of the bridge circuit 120. The first impedance Z1 122 and the second impedance Z2 124, which form a first branch of the bridge circuit 120, are coupled in parallel with the third impedance Z3 126 and the fourth impedance Z4 128, which form a second branch of the bridge circuit 120.

A sensor 130 capable of detecting the electrical signal 102 is coupled between the first node 132 and the second node 134. In an embodiment, the sensor 132 is a voltage measuring device. In an embodiment, if the electrical signal 102 is a time dependent signal or a time varying signal such as an AC and a pulse signal, or a combination thereof, then the sensor 130 may be an oscilloscope or a phase lock-in amplifier instrument. The pulse width, amplitude and periodicity, or a combination thereof, of the pulsed signal may be constant or irregular. The first node 132 and the second node 134 may also be described as the two floating nodes of the bridge circuit 120 since these nodes are floating, e.g., neither one of these nodes are directly coupled to the electrical signal source 110. In an exemplary, non-depicted embodiment, the bridge circuit 120 is internal to the DUT 190. That is, all four impedances are built into the DUT 190 and are accessible by the corresponding bond pads.

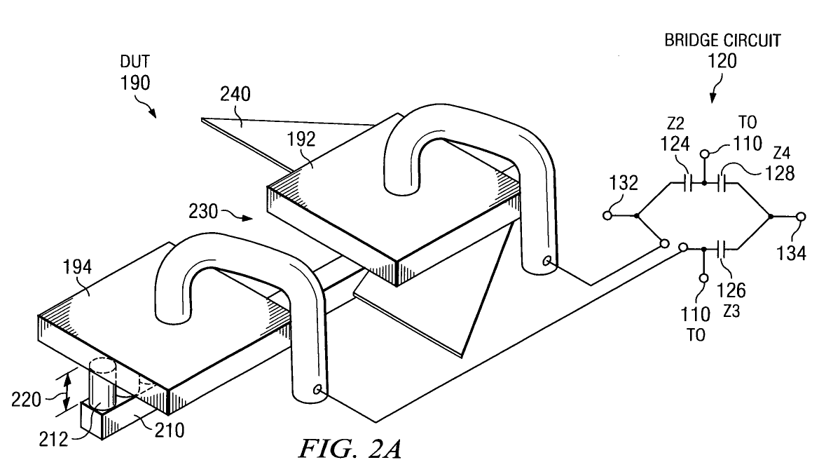

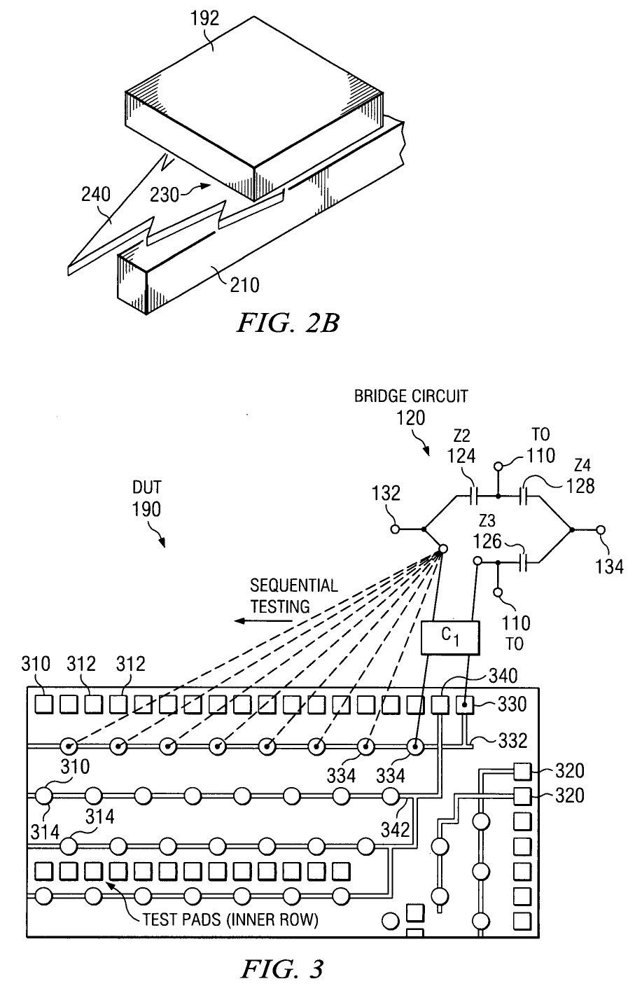

In the depicted embodiment, the device under test (DUT) 190 has a plurality of bond pads (not shown) including a test bond pad 192 and an access bond pad 194. The test bond pad 192 may be selectable as any one of the plurality of bond pads other than the access bond pad 194. The selection may be performed in accordance with a test plan and may include sequential or random selection of each one of the plurality of bond pads, or may include only particular ones of the plurality of bond pads. In a particular embodiment, the DUT 190 is a semiconductor device having the test bond pad 192 and the access bond pad 194. In the depicted embodiment, an impedance measurable across the test bond pad 192 and the access bond pad 194 is the same as the first impedance Z1 122, although it is understood that the impedance measurable across the test bond pad 192 and the access bond pad 194 may be selectable to be any one of the four impedances. Additional detail of the impedance measurable across the test bond pad 192 and the access bond pad 194 of the DUT 190 is described with reference to FIG. 2.

The bridge circuit 120 is configured by selecting particular values for three out of the four impedances in dependence of the impedance measurable across the test bond pad 192 and the access bond pad 194. A voltage V12 measured by the sensor 130 across the first node 132 and the second node 134 is defined by an equation 100 as follows:

V12=[(Z3*Z2−Z1*Z4)*VS]/[(Z1+Z2)+(Z3+Z4)] Equation 100

where VS is the voltage applied to the bridge circuit 120, e.g., a bias voltage of the electrical signal source 110. The sensor 130 is operable to measure an initial value of the V12 before a stimulus 140 is applied to the DUT 190, and is operable to also measure a final value of the V12 after the stimulus 140 is applied to the DUT 190. As described earlier, the stimulus 140, which may be in the form of wire bonding, ball bonding, or temperature cycling, induces stress in the DUT 190, thereby potentially generating a defect in the DUT 190. If the initial value of the V12 is different than the final value of the V12 by a threshold, then the change in the value is indicative of a presence of a defect such as a crack in the DUT 190.

In an embodiment, the DUT 190 is at least one of a microprocessor, an application specific integrated circuit (ASIC), a digital signal processor, a radio frequency chip, a memory, a microcontroller and a system-on-a-chip or a combination thereof. As described earlier, the electrical signal 102 may be selectable to be one of a direct current (DC) signal and an alternating current (AC) signal. For a DC signal the in series resistances of the interconnect paths are substantially equal to zero ohms, and parallel resistances associated with an impedance such as a capacitor are virtually infinite ohms. An AC signal may be used to detect wirebond delamination within the test bond pad 192 by detecting a change in a phase relationship of the voltage measured across the two floating nodes. The wirebond delamination causes an increase in series resistance of the interconnect paths that may be detectable by the sensor 130.

FIG. 2A illustrates a view in perspective of an internal structure of a portion of the DUT 190 described with reference to FIG. 1, according to an embodiment. In the depicted embodiment, the DUT 190 includes the test bond pad 192 and the access bond pad 194. The access bond pad 194 is electrically coupled to a conductive dummy finger element 210 (or a conductive lead) by vias 212. The dummy finger element 210 is disposed at a height h 220 below the access bond pad 194 and the test bond pad 192. Dielectric material 230 is disposed below the access bond pad 194 and the test bond pad 192 to completely surround the conductive dummy finger element 210, and the vias 212. The dielectric material 230 may include a crack 240.

FIG. 2B illustrates a view in perspective of a presence of the crack 240 in the internal structure of a portion of the DUT 190 described with reference to FIG. 2A, according to an embodiment. Referring to FIGS. 2A and 2B, the test bond pad 192 forms one plate of a capacitance C, the dummy finger element 210 forms another plate of the capacitance C and the two plates are separated by the dielectric material 230. In the depicted embodiment, a crack 240 is capable of being formed in the dielectric material 230 disposed between the two plates. The impedance across the test bond pad 192 and the access bond pad 194 is the capacitance C formed between the test bond pad 192 and the dummy finger element 210 separated by the dielectric material 230 having the crack 240. In an embodiment, the capacitance C, which may change in dependence of the dimensions and the position of the crack 240, is selectable as one of the four impedances included in the bridge circuit 120. In this embodiment, the remaining three impedances of the bridge circuit 120 are also selectable as capacitances. Additional detail of a layout of a plurality of dummy finger elements coupled to at least one access pad is described with reference to FIG. 3.

Referring to FIGS. 2A and 2B, a value of the capacitance C is defined by an equation 200 as follows:

C=k*epsilon*area/h Equation 200

where k is the effective dielectric constant, epsilon is the permittivity of free space which is equal to 8.85*10 raised to the power of (−12) farads per meter, area is the area of the dummy finger element 210 which is equal to its width*length, and h is a height (or spacing between the test bond pad 192 and the dummy finger element 210) of the dielectric material 230. For example, for a particular DUT, a test bond pad has dimensions of 55 micrometers*55 micrometers, the area of a dummy finger element is 55 micrometers*0.1 micrometers, height h is 0.1 micrometers, and the effective dielectric constant k is 3.5. In this example, a value of the capacitance C is about 1.7 femtofarad (fF).

A presence of the crack 240 in the dielectric material 230 disposed between the test bond pad 192 and the dummy finger element 210 changes the effective dielectric constant k of the capacitance C as defined in equation 200, and hence changes the impedance between the test bond pad 192 and the access bond pad 194. The change in the impedance is dependent on various factors such as dimensions of the crack 240 (length, width, and position relative to the plates), and presence or absence of ambient gases in the crack 240, which may change the effective dielectric constant k.

A change in the impedance between the test bond pad 192 and the access bond pad 194 is detectable and measurable by the sensor 130 described with reference to FIG. 1. In an exemplary, non-depicted embodiment, the capacitance C, which is the capacitance between the test bond pad 192 and the access bond pad 194 having a value of 1.5 fF, is configured as impedance Z1 122 of the bridge circuit 120. The remaining three impedances (Z2 124, Z3 126, and Z4 128) of the bridge circuit 120 are configured to be a capacitance, each having a value of 1 fF.

Referring to FIGS. 1, 2A and 2B, if a value of the electrical signal 102 generated by the electrical signal source 110 applied across the bridge circuit 120 is 1.0 volts, then a voltage V12 measurable (or computable) across the two floating nodes is −0.100 volts, using equation 100. Thus, −0.100 volts is the initial value of the electrical signal measured (or computed per equation 100) before providing the stimulus 140 to the DUT 190. If a crack is formed in response to the stimulus 140, then the capacitance C increases by 0.1 fF to 1.6 fF. The change in the value of the capacitance is detectable as a change in the value of V12 from −0.100 volts to −0.115 volts that is measurable across the two floating nodes. The voltage difference of −15 millivolts is detectable and measurable by the sensor 130. If the effective dielectric constant k per equation 200 doubles to double the value of capacitance from 1.5 fF to 3.0 fF, then the resulting change is about −233 millivolts.

The test system 100 advantageously provides non-destructive repeatable, accurate, electrical measurement techniques to verify whether the DUT 190 is substantially free from a presence of a crack, fracture or similar defect disposed below interconnections such as the test bond pad 192. A substantially constant value of the voltage V12, measured before and after providing the stimulus 140 to the DUT 190, is indicative of no change in the capacitance C, and hence an absence of the crack 240. If the voltage across the two floating nodes is continuously monitored, then test data related to the change in the capacitance C may be collected and recorded as a function of time. The test data may be then used to establish the pass/fail status of the DUT 190, track behavior of a crack as a function of time over repeated stress cycles, co-relate induced stress and crack formation, perform defect analysis, and similar others.

A sign of the change in the voltage before and after the stimulus 140 is indicative of whether the capacitance of the test bond pad 192 has either increased (negative shift) or decreased (positive shift) compared to the original capacitance. In a particular embodiment, if the crack is hermetic, then the creation of space within the dielectric material 230 is essentially a vacuum environment having an effective dielectric constant k of approximately one. If original dielectric constant for a BEOL layer is 4.2 and the dielectric constant changes to one due to the hermetic crack, then the change in the dielectric constant is 3.2. If length of a dummy finger element is 55 micrometers, width is 1.05 micrometers, and the dielectric thickness is 0.6 micrometers, then a change in the capacitance C computed before and after the crack per equation 200 is −27.3 fF or a −76% change from the original capacitance of 35.8 fF. This change is detectable by the sensor 130. If a crack is formed across a dummy finger element, the change is less since the net capacitance consists of two parallel capacitors. If a crack compromises hermiticity, then the effective dielectric constant k may be doubled from 4.2 to about 10. The change in capacitance before and after the crack will increases from 35.8 fF to about 49.4 fF or increase by 135%.

FIG. 3 illustrates a layout of a plurality of bond pads 310 of the DUT 190 described with reference to FIGS. 1, 2A, and 2B, according to an embodiment. In the depicted embodiment, the plurality of bond pads 310 include a plurality of wire bond pads 312 that are arranged along a periphery, a plurality of ball bond pads 314 that are disposed on a top surface, and a plurality of access pads 320 arranged along the periphery. The plurality of access pads 320 includes a first access pad 330 coupled to a first dummy finger element 332 disposed below corresponding ones of the plurality of ball bond pads 314, and a second access pad 340 that is coupled to a second dummy finger element 342 disposed below corresponding ones of the plurality of ball bond pads 314. In the depicted embodiment, the bridge circuit 120 is coupled to the first access pad 330, which is equivalent to the access bond pad 194, and to one of the plurality of bond pads 314, which is equivalent to the test bond pad 192. Each one of the plurality of bond pads 314 may be selected as the test bond pad 192 for sequential testing of the plurality of bond pads 310. In an exemplary, non-depicted embodiment, disposed below each one the plurality of bond pads 310 is a corresponding dummy finger element that is electrically coupled to at least one access pad. The test bond pad 192 is selectable to be anyone of the plurality of bond pads 310 except the plurality of access pads 320.

In an embodiment, fabrication of the dummy finger elements 332 and 342 uses the same processes as the fabrication of a dummy metal element. The dummy finger elements 332 and 342 having narrow widths do not substantially alter the interconnect footprint around the bond pads and do not utilize excessive amounts of valuable real estate of an IC chip. Since the dummy finger elements 332 and 342 are floating conductive elements, they may be susceptible to external noise. Effective grounding and proper shielding of the DUT 190 may reduce the undesirable effects caused by the external noise.

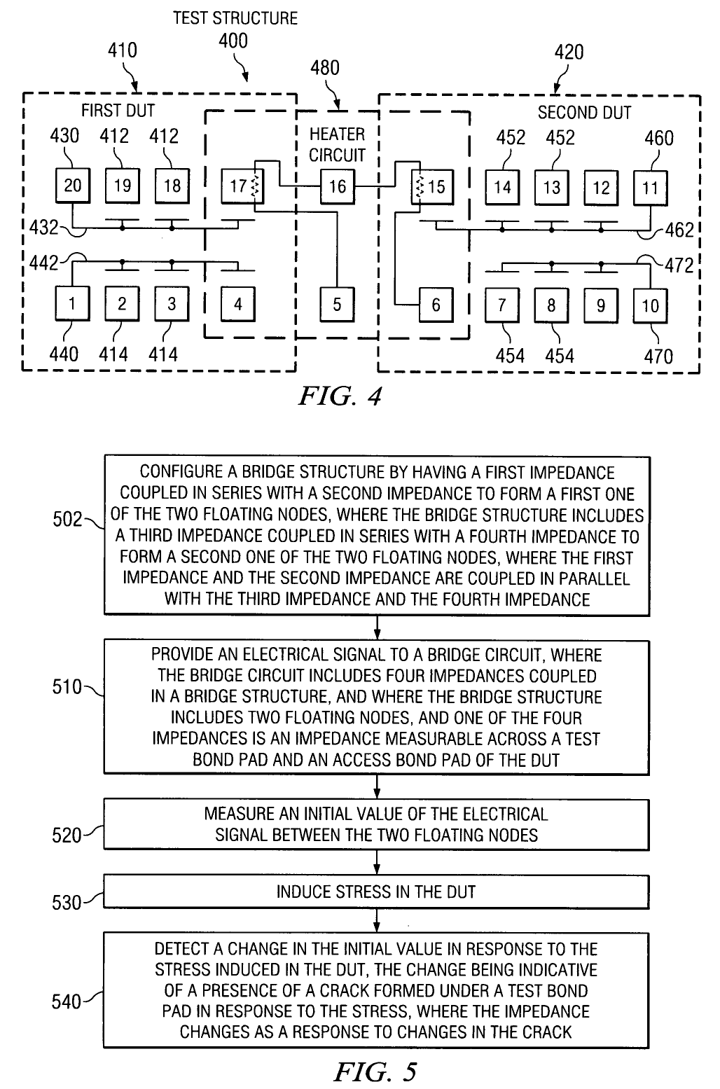

FIG. 4 illustrates a schematic layout of a test structure 400 for parallel testing two DUT's, according to an embodiment. In the depicted embodiment, the test reticle 400 includes a first DUT 410 and a second DUT 420 each of which may be tested individually or concurrently for a presence of a crack (not shown). In a particular embodiment, each one of the first DUT 410 and the second DUT 420 includes two structures (one per row) that are operable to perform functions similar to the DUT 190 described with reference to FIG. 1. DUT's 410 and 420 differ slightly in the layout of the bridge element 210 underneath a bond pad of interest. The first DUT 410 includes a first plurality of bond pads 412, a second plurality of bond pads 414, a first access bond pad 430 coupled to a first dummy finger element 432, and a second access bond pad 440 coupled to a second dummy finger element 442. Similarly, the second DUT 420 includes a third plurality of bond pads 452, a fourth plurality of bond pads 454, a third access bond pad 460 coupled to a third dummy finger element 462, and a fourth access bond pad 470 coupled to a fourth dummy finger element 472. The test bond pad 192 described with reference to FIG. 1 is selectable as any one of the first plurality of bond pads 412, the second plurality of bond pads 414, the third plurality of bond pads 452, and the fourth plurality of bond pads 454. Common to the first DUT 410 and the second DUT 420 is a heater circuit 480. The heater circuit 480 provides the stimulus 140 to the DUT's 410 and 420. Two heater elements respectively disposed under a bond pad 17 of the first plurality of bond pads 412 and a bond pad 15 of the third plurality of bond pads 452 are operable to induce local stress by controllably heating area below the pads of the DUT's 410 and 420, and can, as a means of testing, potentially calibrate the amount of capacitance change associated with small changes in bond pad to bridge element spacing.

FIG. 5 is a flow chart illustrating a method for testing a device under test (DUT), according to an embodiment. In a particular embodiment, the method is used to test the DUT's 190, 410, and 420 described with reference to FIGS. 1, 2A, 2B, 3, and 4. At step 510, an electrical signal is provided to a bridge circuit. The bridge circuit includes four impedances coupled in a bridge structure having two floating nodes. One of the four impedances is an impedance measurable across a test bond pad and an access bond pad of the DUT. At step 520, an initial value of the electrical signal is measured between the two floating nodes. At step 530, a stress is induced in the DUT, e.g., by temperature cycling. At step 540, a change in the electrical signal is detected in response to the stress. The change is indicative of a presence of a crack formed under a test bond pad in response to the induced stress. The change is indicative of a presence of a crack formed under a test bond pad in response to the stress. The impedance changes as a response to changes in the crack characteristics.

Various steps described above may be added, omitted, combined, altered, or performed in different orders. For example, step 502 may be added before the step 510. At step 502, the bridge structure is configured by having a first impedance coupled in series with a second impedance to from a first one of the two floating nodes, and a third impedance coupled in series with a fourth impedance to form a second one of the two floating nodes. The first impedance and the second impedance are coupled in parallel with the third impedance and the fourth impedance.

Several advantages are achieved by the method and system according to the illustrative embodiments presented herein. The embodiments advantageously provide for non-destructive repeatable, accurate, electrical measurement techniques to verify that the DUT is substantially free from a presence of a crack, fracture or similar defect disposed below interconnections such as bond pads. The embodiments advantageously provide an electrically sensitive bridge circuit to detect cracks by detecting a change in impedance (such as a capacitance) measurable between a test bond pad and an access bond pad. A dummy finger element structure is advantageously disposed under the test bond pad to form a capacitance. A formation of a crack causes a change in a dielectric property of the capacitance, and hence in a value of the capacitance. The dummy finger element does not substantially alter the interconnect footprint around bond pads and does not utilize excessive amounts of valuable real estate of an IC chip. Changes to the capacitance may be monitored over time, e.g., after burn-in, or after inducing environmental stress on the DUT. The embodiments advantageously provide information about a crack, e.g., whether a crack is hermetic or non-hermetic by measuring differences in the sign and magnitude of the change in the bridge circuit. The embodiments advantageously enable semiconductor device manufacturers to improve product quality and reliability, reduce the overall testing costs, and enable increased production.

Although illustrative embodiments have been shown and described, a wide range of modification, change and substitution is contemplated in the foregoing disclosure and in some instances, some features of the embodiments may be employed without a corresponding use of other features. Those of ordinary skill in the art will appreciate that the hardware and methods illustrated herein may vary depending on the implementation. For example, while certain aspects of the present disclosure have been described in the context of using an external bridge circuit, and an external stimulus, e.g., external to a DUT, for detecting a presence of a crack in the DUT, those of ordinary skill in the art will appreciate that the processes disclosed herein are capable of detecting a presence of the crack in the DUT having a built-in bridge circuit, and a built-in local heater to provide the stimulus.

The methods and systems described herein provide for an adaptable implementation. Although certain embodiments have been described using specific examples, it will be apparent to those skilled in the art that the invention is not limited to these few examples. The benefits, advantages, solutions to problems, and any element(s) that may cause any benefit, advantage, or solution to occur or become more pronounced are not to be construed as a critical, required, or an essential feature or element of the present disclosure.

The above disclosed subject matter is to be considered illustrative, and not restrictive, and the appended claims are intended to cover all such modifications, enhancements, and other embodiments, which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A test system for testing a presence of a crack, the test system comprising:
an electrical signal source capable of providing an electrical signal;
a bridge circuit coupled to the electrical signal source, the bridge circuit including four impedances coupled in a bridge structure, the bridge structure having two floating nodes;
a device under test (DUT) having a test bond pad and an access bond pad, wherein an impedance across the test bond pad and the access bond pad is one of the four impedances;
a stimulus to induce stress in the DUT; and
a sensor coupled between the two floating nodes, the sensor being operable to detect a change in a value of the electrical signal in response to the stimulus, wherein the change is triggered by the presence of the crack under the test bond pad caused by the stress, wherein the impedance changes as a response to changes in the crack.

2. The test system of claim 1, wherein the bridge circuit includes a first impedance coupled in series with a second impedance to form a first one of the two floating nodes, wherein the bridge circuit includes a third impedance coupled in series with a fourth impedance to form a second one of the two floating nodes, wherein the first impedance and the second impedance are coupled in parallel with the third impedance and the fourth impedance.

3. The test system of claim 1, wherein the bridge structure includes three out of the four impedances having an adjusted value in dependence of the impedance across the test bond pad and the access bond pad, wherein the sensor is operable to measure an initial value of the electrical signal between the two floating nodes before the testing, wherein the two floating nodes are not directly coupled to the electrical signal source.

4. The test system of claim 1, wherein the access bond pad is coupled to a dummy finger element disposed below the test bond pad, wherein the impedance between the test bond pad and the dummy finger element is a capacitance, wherein the capacitance changes in dependence of the crack.

5. The test system of claim 1, wherein each one of the four impedances is a capacitance.

6. The test system of claim 1, wherein the change in the impedance is dependent on a length of the crack and is dependent on a change in a dielectric constant due to the crack.

7. The test system of claim 1, wherein the electrical signal source provides one of a direct current (DC) signal and a time varying signal, wherein the time varying signal is one of an alternating current (AC) signal and a pulse signal, or a combination thereof.

8. The test system of claim 1, wherein the stimulus is provided by a heater device located within the DUT, the heater device being operable to temperature cycle the DUT.

9. The test system of claim 1, wherein the DUT is at least one of a microprocessor, an application specific integrated circuit (ASIC), a digital signal processor, a radio frequency chip, a memory, a microcontroller and a system-on-a-chip or a combination thereof.

10. A method for testing a device under test (DUT), the method comprising:
providing an electrical signal to a bridge circuit, wherein the bridge circuit includes four impedances coupled in a bridge structure, wherein the bridge structure includes two floating nodes, wherein one of the four impedances is an impedance measurable across a test bond pad and an access bond pad of the DUT;
measuring an initial value of the electrical signal between the two floating nodes;
inducing stress in the DUT; and
detecting a change in the initial value in response to the stress induced in the DUT, the change being indicative of a presence of a crack formed under a test bond pad in response to the stress, wherein the impedance changes as a response to changes in the crack.

11. The method of claim 10 further comprising:
configuring the bridge structure by having a first impedance coupled in series with a second impedance to from a first one of the two floating nodes, wherein the bridge structure includes a third impedance coupled in series with a fourth impedance to form a second one of the two floating nodes, wherein the first impedance and the second impedance are coupled in parallel with the third impedance and the fourth impedance.

12. The method of claim 10, wherein the detection of the change includes:
measuring another value of the electrical signal between the two floating nodes in response to the stress; and
determining whether the another value is equal to the initial value.

13. The method of claim 10, wherein the access bond pad is coupled to a dummy finger element disposed below the test bond pad, wherein the impedance is a capacitance measured between the test bond pad and the dummy finger element, wherein the capacitance changes in dependence of the crack.

14. The method of claim 10, wherein the DUT is at least one of a microprocessor, an application specific integrated circuit (ASIC), a digital signal processor, a radio frequency chip, a memory, a microcontroller and a system-on-a-chip or a combination thereof.

15. The method of claim 10, wherein the stress is induced by cycling a temperature of the DUT.

16. The method of claim 10, wherein the electrical signal is one of a direct current (DC) signal and a time varying signal, wherein the time varying signal is one of an alternating current (AC) signal and a pulse signal, or a combination thereof.

17. The method of claim 10, wherein the change in the impedance is dependent on a length of the crack and is dependent on a change in a dielectric constant of the crack.

18. A semiconductor device comprising:
a plurality of conductive pads including a test bond pad and an access bond pad;
a plurality of dummy finger elements electrically coupled to the access bond pad, wherein each one of the plurality of dummy finger elements is disposed below a corresponding one of the plurality of conductive pads; and
a dielectric material disposed between the each one of the plurality of dummy finger elements and the corresponding one of the plurality of conductive pads to from a plurality of impedances, wherein a change in an impedance measurable between the test bond pad and the access bond pad is indicative of a presence of a crack in the dielectric material.

19. The device of claim 18, wherein the change in the impedance is detected by a bridge circuit coupled to the test bond pad and the corresponding one of the plurality of dummy finger elements coupled through the access pad, wherein the test bond pad is any one of the plurality of conductive pads other than the access bond pad.

20. The device of claim 18, wherein the change in the impedance is dependent on a length of the crack and is dependent on a change in a dielectric constant of the dielectric material of the crack.
